(19) United States
(12) Patent Application Publication
(10) Pub. No.: US 2026/0005655 A1
(43) Pub. Date: Jan. 1, 2026

(54) INPUT PREMATCH CIRCUITS FOR PSUDO-INVERSE CLASS F AMPLIFIER

(71) Applicant: NXP USA, Inc., Austin, TX (US)

(72) Inventors: Aniket Anant WADODKAR, Gilbert, AZ (US); Jitesh VASWANI, Gilbert, AZ (US); Laure BOLLINGER, Cugnaux (FR); Joseph Gerard SCHULTZ, Wheaton, IL (US); Ricardo Uscola, Tempe, AZ (US)

(21) Appl. No.: 18/950,968

(22) Filed: Nov. 18, 2024

(30) Foreign Application Priority Data
Jul. 1, 2024 (EP) 24306068.8

(51) Int. Cl. H03F 1/56; H01L 23/66; H03F 1/02; H03F 3/24

(52) U.S. Cl. CPC H03F 1/565; H01L 23/66; H03F 1/0288; H03F 3/245; H01L 2223/6611; H01L 2223/6655; H03F 2200/225; H03F 2200/451

(57) ABSTRACT

A device may include an amplifier input, a transistor die including a transistor and a transistor input terminal, and a device may include a fundamental frequency impedance matching circuit coupled between the amplifier input and the transistor input terminal, wherein the fundamental frequency impedance matching circuit is configured as a dual input T-match (DITM) circuit including a first shunt capacitor and a second shunt capacitor, wherein a first terminal of the first shunt capacitor is connected to the amplifier input by a first bond wire, the first terminal of the first shunt capacitor is connected to a first terminal of the second shunt capacitor by a second bond wire, and the first terminal of the second shunt capacitor is connected to the transistor input terminal by a third bond wire. A harmonic frequency termination circuit may be coupled between the transistor input terminal and a first ground reference node.

### CROSS-REFERENCE TO RELATED APPLICATIONS

This application claims priority under 35 U.S.C. § 119 to European patent application no. 24306068.8, filed Jul. 1, 2024, the contents of which are incorporated by reference herein.

### TECHNICAL FIELD

Embodiments of the subject matter described herein relate generally to radio frequency (RF) amplifiers, and more particularly to power transistor devices and amplifiers with impedance matching and harmonic frequency termination circuits.

### BACKGROUND

Wireless communication systems employ power amplifiers for increasing the power of radio frequency (RF) signals. Input impedance matching circuits are commonly implemented at the input of a power amplifier to enable best performance. In an amplifier that includes a power transistor device characterized by nonlinear input capacitance, the power transistor may generate significant undesirable signal energy at harmonics of the fundamental frequency of operation of the amplifier, and particularly at a second harmonic frequency. This undesirable second harmonic frequency signal energy may limit the achievable performance of the amplifier. Accordingly, a second harmonic termination circuit may play an important role in the overall performance of a power amplifier design that includes a power transistor device with nonlinear input capacitance.

### SUMMARY

This Summary section is neither intended to be, nor should be, construed as being representative of the full extent and scope of the present disclosure. Additional benefits, features and embodiments of the present disclosure are set forth in the attached figures and in the description hereinbelow, and as described by the claims. Accordingly, it should be understood that this Summary section may not contain all of the aspects and embodiments claimed herein.

Additionally, the disclosure herein is not meant to be limiting or restrictive in any manner. Moreover, the present disclosure is intended to provide an understanding to those of ordinary skill in the art of one or more representative embodiments supporting the claims. Thus, it is important that the claims be regarded as having a scope including constructions of various features of the present disclosure insofar as they do not depart from the scope of the methods and apparatuses consistent with the present disclosure (including the originally filed claims). Moreover, the present disclosure is intended to encompass and include obvious improvements and modifications of the present disclosure.

In some aspects, the techniques described herein relate to a radio frequency amplifier, including: an amplifier input; a transistor die including a transistor and a transistor input terminal; a fundamental frequency impedance matching circuit coupled between the amplifier input and the transistor input terminal, wherein the fundamental frequency impedance matching circuit is configured as a dual input T-match (DITM) circuit including a first shunt capacitor and a second shunt capacitor, wherein a first terminal of the first shunt capacitor is connected to the amplifier input by a first bond wire, the first terminal of the first shunt capacitor is connected to a first terminal of the second shunt capacitor by a second bond wire, and the first terminal of the second shunt capacitor is connected to the transistor input terminal by a third bond wire; and a harmonic frequency termination circuit coupled between the transistor input terminal and a first ground reference node.

In some aspects, the techniques described herein relate to a packaged radio frequency amplifier, including: a substrate; an input lead on a surface of the substrate; an output lead on the surface of the substrate; a transistor die on the substrate, wherein the transistor die includes a transistor and a transistor input terminal; a fundamental frequency impedance matching circuit coupled between the amplifier input and the transistor input terminal, wherein the fundamental frequency impedance matching circuit is configured as a dual input T-match (DITM) circuit; and a harmonic frequency termination circuit coupled between the transistor input terminal and a first ground reference node.

In some aspects, the techniques described herein relate to a Doherty amplifier, including: a main amplifier path; and a peaking amplifier path, and wherein at least one of the main amplifier path and the peaking amplifier includes a radio frequency amplifier, the radio frequency amplifier including: a substrate; an input lead on a surface of the substrate; an output lead on the surface of the substrate; a transistor die on the substrate, wherein the transistor die includes a transistor and a transistor input terminal; a fundamental frequency impedance matching circuit coupled between the amplifier input and the transistor input terminal, wherein the fundamental frequency impedance matching circuit is configured as a dual input T-match (DITM) circuit; and a harmonic frequency termination circuit coupled between the transistor input terminal and a first ground reference node.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic diagram of a radio frequency power amplifier circuit.

FIG. 2 is a top view of an embodiment of a packaged radio frequency amplifier device that embodies the amplifier of FIG. 1.

FIG. 3 is a side view of the packaged radio frequency amplifier device of FIG. 2.

FIG. 4 is a simplified schematic diagram of a Doherty power amplifier in which two parallel instances of the radio frequency power amplifier circuit of FIG. 2 may be implemented.

FIG. 5 is a schematic diagram of another embodiment of a radio frequency power amplifier circuit.

FIG. 6 is a top view of an embodiment of a packaged RF amplifier device 600 that embodies amplifier 500 of FIG. 5.

### DETAILED DESCRIPTION OF THE ILLUSTRATED EMBODIMENTS

The present invention generally relates to radio frequency (RF) amplifiers, and more particularly to power transistor devices and amplifiers with impedance matching and harmonic frequency termination circuits.

In an amplifier that includes a power transistor device characterized by nonlinear input capacitance (e.g., a device incorporating gallium nitride (GaN) transistor(s)), the power transistor may generate significant undesirable signal energy at harmonics of the fundamental frequency of operation of the amplifier, and particularly at a second harmonic frequency. Accordingly, a second harmonic frequency termination circuit (“harmonic termination circuit”) may be included at the input of such an amplifier.

A typical harmonic termination circuit includes a series-coupled inductor-capacitor (LC) circuit connected between the input (e.g., gate) of a power transistor device and a ground reference node (i.e., the harmonic termination circuit is connected in a shunt configuration). The series LC harmonic termination circuit is essentially configured to resonate at or near the second harmonic frequency, in order to shunt signal energy at the second harmonic frequency to ground. However, for some frequency ranges, the capacitance value of the harmonic termination circuit capacitor may undesirably affect the operation of input fundamental frequency impedance matching circuitry (“fundamental match circuitry”), thus degrading the overall performance of the amplifier. More particularly, some fundamental match circuits include a shunt inductance, which may be implemented using a set of bondwires. The inductance of the LC harmonic termination circuit also may be implemented using a set of bondwires, and when a higher capacitance value is utilized in the LC harmonic termination circuit, the bondwire inductances of the fundamental match and the harmonic termination circuit may undesirably interact and degrade amplifier performance (e.g., by changing the network resonance of the fundamental match circuitry, thus negatively impacting the amplifier gain).

For a power transistor device that is configured to operate at a relatively low fundamental frequency of operation (e.g., below 1 gigahertz (GHz)), the capacitance value of a harmonic termination circuit that is needed to create an effective second harmonic termination is fairly high, when compared with capacitance values that may be utilized in amplifiers that operate at higher frequencies. However, the relatively high capacitance value utilized in a harmonic termination circuit in a lower frequency amplifier may produce undesirable interactions between the capacitance of the harmonic termination circuit and the fundamental match circuitry. More particularly, such a harmonic termination circuit may create a higher high-pass cutoff, meaning that the effective inductance for the high pass resonance may be reduced, which in turn may degrade the amplifier gain. In other words, for an amplifier designed to operate at a relatively low fundamental frequency of operation, a typical harmonic termination circuit may not be sufficiently transparent to the fundamental matching circuitry and may undesirably load the fundamental matching circuitry.

In an amplifier operating in a pseudo inverse F class mode of operation (described below), the amplifier topology has been implemented using input T-match impedance match network combined with an input harmonic trap circuits (referred to as T+IHT match circuits), as well as dual input T match (DITM) circuit, with DITM circuits often being the preferred choice for input matching and harmonic control. Notably, an input T match+IHT circuit allows the amplifier designer to place the amplifier's second harmonic in a best possible region consider the amplifiers desired use but can suffer from low gain and low input impedance. In contrast, input DITM circuits can offer both high gain and better input impedance matches but can sacrifice second harmonic location placement, resulting in suboptimal amplifier efficiency.

To summarize, an input T Match (ITM) circuit may operate as a low pass network to provide some fundamental frequency matching but can lack effective second harmonic frequency control. As a result, in amplifiers that incorporate ITM input circuits the second harmonic frequency may be located poorly (e.g., within a Smith chart) result in inefficient amplifier performance.

Conversely, an Input T Match+Input Harmonic Trap (ITM+IHT) circuit can operate as a low pass network with the addition of an LC network acting, which can operate as a harmonic trap. This input circuit does provide some flexibility in moving the input second harmonic frequency into a more favorable region for amplifier operations, but this topology is forced to trade off amplifier gain to limit potential instabilities. Additionally, because these circuits are often implemented as a single-section low pass network, such a configuration does not transform the relatively low input impedance of high periphery GaN transistor die sufficiently to allow this circuit to provide adequate impedance matching at the printed circuit board (PCB) level.

Double Input T Match (DITM) circuits can operate as two-stage low pass networks. The two stages operate to provide acceptable levels of input impedance to provide an adequate match to the amplifier die's PCB. Although this configuration can operate to place the second harmonic frequency in a better location than the ITM approach describes above, the DITM circuit is not fully optimized because the circuit generally provides inadequate control of second harmonic frequencies which can, again, reduce amplifier efficiency. In particular, in the DITM configuration, in which the input matching circuit includes an output inductor (typically implemented by a bond wire), the inductance of that output inductor of the input matching circuit can affect the fundamental and second harmonics of the amplifier. Consequently, in a DITM circuit, it is generally desirable to provide a high inductance in the circuit's output inductor to high amplifier gain, but that high inductance can move the amplifier's second harmonic frequency in a non-optimum direction thereby sacrificing amplifier power. Conversely, if the inductance of the output inductor is reduced to improve the second harmonic frequency location, input resonance is moved up in frequency and away from the band of operation of the amplifier, which can reduce amplifier gain significantly and makes input impedance unfavorable for impedance matching on PCB.

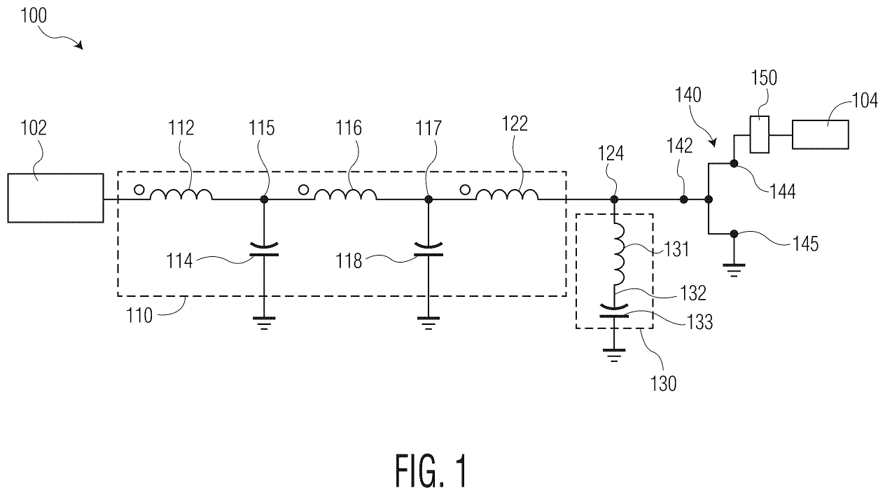

FIG. 1 is a schematic diagram of an RF power amplifier circuit 100. Power amplifier circuit 100 includes an input lead 102, an input fundamental frequency impedance matching circuit 110 (“fundamental match circuit”), a second harmonic frequency termination circuit 130 (“harmonic termination circuit”), a transistor 140, and an output lead 104, in an embodiment. Each of the input and output leads 102, 104 may be more generally referred to as an “RF input/output (I/O).” Further, reference is made below to a “ground reference node.” In various embodiments, a “ground reference node” is a conductive feature of a device or module (e.g. a conductive flange, a die pad, or a conductive ground plane in a printed circuit board (PCB) based module) to which terminals of various components of the power amplifier circuit 100 are coupled, where that conductive feature may be coupled to system ground (e.g., to a zero volt ground reference or to another voltage reference) when the device or module is incorporated into a larger electrical system.

Input lead 102 and output lead 104 each may include a conductor (e.g., a package lead), which is configured to enable the power amplifier circuit 100 to be electrically coupled with external circuitry (not shown). More specifically, the input and output leads 102, 104 are physically positioned to span between the exterior and the interior of a device package or module, in an embodiment. Fundamental match circuit 110 and harmonic termination circuit 130 are electrically coupled between the input 102 and an input terminal 142 of transistor 140 (also referred to as a “transistor input terminal”, a “control terminal” or a “gate terminal”). A first current-carrying terminal 144 of transistor 140 (e.g., the drain terminal) is coupled to the output 104 through output network 150, that may include various impedance matching and filtering components. A second current-carrying terminal 145 of transistor 140 (e.g., the source terminal) is coupled to a ground reference node.

According to an embodiment, transistor 140 is the primary active component of circuit 100. Transistor 140 includes a control terminal 142 and two current-carrying terminals 144, 145, where the current-carrying terminals 144, 145 are spatially and electrically separated by a variable-conductivity channel. For example, transistor 140 may be a field effect transistor (FET), which includes a gate terminal (i.e., control terminal 142), a drain terminal (i.e., first current-carrying terminal 144), and a source terminal (i.e., second current-carrying terminal 145). According to an embodiment, and using nomenclature typically applied to FETs in a non-limiting manner, the gate terminal 142 of transistor 140 is coupled to the fundamental match circuit 110 and the harmonic termination circuit 130, the drain terminal 144 of transistor 140 is coupled to the output 104, and the source terminal 145 of transistor 140 is coupled to ground (or another voltage reference). Through the variation of control signals provided to the gate terminal of transistor 140, the current between the current-carrying terminals of transistor 140 may be modulated.

According to one or more embodiments, transistor 140 is a III-V field effect transistor (e.g., a high electron mobility transistor (HEMT)), which has a nonlinear input capacitance and a relatively low drain terminal-source terminal capacitance, Cds, when compared with a silicon-based FET (e.g., a laterally-diffused metal oxide semiconductor (LDMOS) FET). According to an embodiment, transistor 140 may have a drain terminal-source terminal capacitance that is less than about 0.2 pF/W. In some embodiments, for example, transistor 140 may have a drain terminal-source terminal capacitance that is in the range of 0.1 pF/W to 0.2 pf/W. Further, in some embodiments, transistor 140 may be a GaN FET, although in other embodiments, transistor 140 may be another type of III-V transistor (e.g., gallium arsenide (GaAs), gallium phosphide (GaP), indium phosphide (InP), or indium antimonide (InSb)), or another type of transistor that has a nonlinear input capacitance and a relatively low drain terminal-source terminal capacitance.

Fundamental match circuit 110 and harmonic termination circuit 130 are electrically coupled between the input 102 and a first terminal 142 of transistor 140 (e.g., the gate terminal). More specifically, the fundamental match circuit 110 is coupled between input 102 and a second node 124, which, in turn, is coupled to the control terminal 142 (e.g., gate terminal) of the transistor 140. Fundamental match circuit 110 is configured to transform (e.g., raise) the gate impedance of transistor 140 to a higher (e.g., intermediate or higher) impedance level (e.g., in a range from about 2 to about 10 ohms or higher) at node 102.

According to an embodiment, fundamental match circuit 110 is configured as a DITM circuit. More specifically, and according to the illustrated embodiment, the fundamental match circuit 110 includes a DITM match circuit composed of inductor 112 (e.g., a set of bond wires) coupled between input 102 and node 115 (also referred to as a “connection node”). Shunt capacitor 114 is coupled between node 115 and a ground reference node. Inductor 116 (e.g., a set of bond wires) is coupled between node 115 and node 117. Shunt capacitor 118 is connected between node 117 and a ground reference node. Finally, fundamental match circuit 110 includes inductor 122 connected between node 117 and node 124.

According to an embodiment, inductors 112, 116, and 122, in combination with shunt capacitors 114 and 118 form the DITM match circuit of fundamental match circuit 110. In some embodiments, inductor 112 may have an inductance that ranges from 30 pico Henries (pH) to 500 pH, shunt capacitor 114 and capacitor 118 may each have capacitances ranging from 10 pico Farads (pF) to 100 pF, and inductor 122 may have an inductance ranging from 30 pH to 700 pH. In other applications, however, these components may be configured differently.

Within amplifier 100, harmonic termination circuit 130 is coupled between the second node 124 (or the input terminal 142 (e.g., gate terminal) of transistor 140) and a ground reference node. Accordingly, the second node 124 basically corresponds to an input to harmonic termination circuit 130. Harmonic termination circuit 130 includes an inductor 131 (e.g., a set of bond wires) coupled between the second node 124 (or the input terminal 142 of the transistor 140) and node 132. Capacitor 133 is connected between node 132 and a ground reference node.

According to an embodiment, the inductance and capacitance values selected for inductor 131 and capacitance 133 are configured to enable harmonic termination circuit 130 to function as a high impedance path to ground (e.g., effectively appearing as an open circuit) for signal energy at the fundamental frequency of operation, and a low impedance path to ground for signal energy at or near a second harmonic frequency (e.g., at the second harmonic frequency or within 10 percent of the second harmonic frequency of amplifier 100).

More specifically, within amplifier 100 the inductances of inductors 112, 116, and 122 are selected to obtain good fundamental performance targeting particular amplifier 100 gain and input impedance characteristics. Harmonic termination circuit 130 is implemented as a second harmonic frequency control network uses the series-connected LC network formed by inductance 131 and capacitance 133 that is connected between gate or input terminal 142 of transistor 140 and a ground reference node and is used to locate the second harmonic frequency in an optimum location.

Although transistor 140 and various elements of the fundamental match circuit 110 and the harmonic termination circuit 130 are shown as singular components, the depiction is for the purpose of ease of explanation only. Those of skill in the art would understand, based on the description herein, that transistor 140 and/or certain elements of the fundamental match circuit 110 and the harmonic termination circuit 130 each may be implemented as multiple components (e.g., connected in parallel or in series with each other). Further, embodiments may include single-path devices (e.g., including a single input lead, output lead, transistor, etc.), dual-path devices (e.g., including two input leads, output leads, transistors, etc.), and/or multi-path devices (e.g., including two or more input leads, output leads, transistors, etc.). Further, the number of input/output leads may not be the same as the number of transistors (e.g., there may be multiple transistors operating in parallel for a given set of input/output leads). The specific description of transistor 140 and various elements of the fundamental match circuit 110 and the harmonic termination circuit 130 thus are not intended to limit the scope of the inventive subject matter only to the illustrated embodiments.

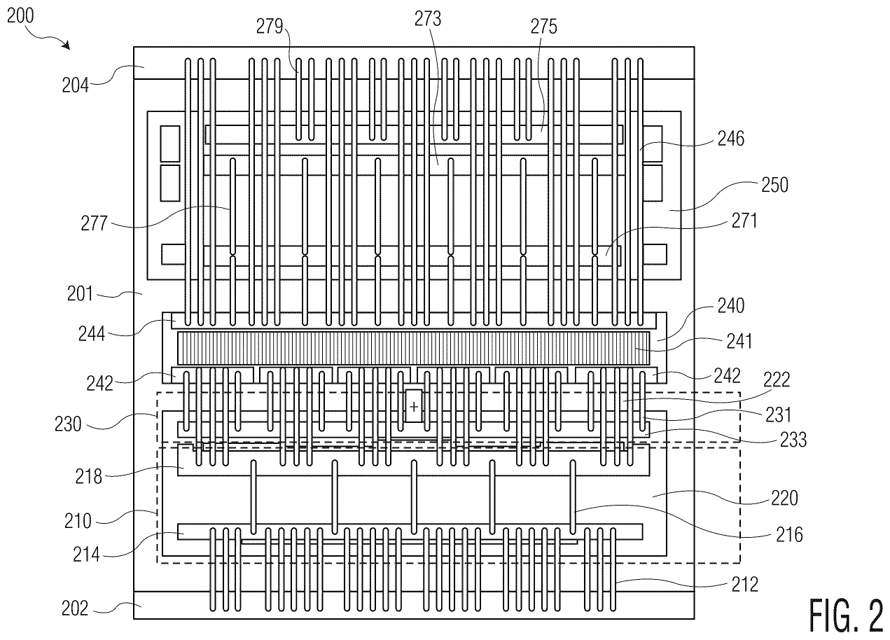

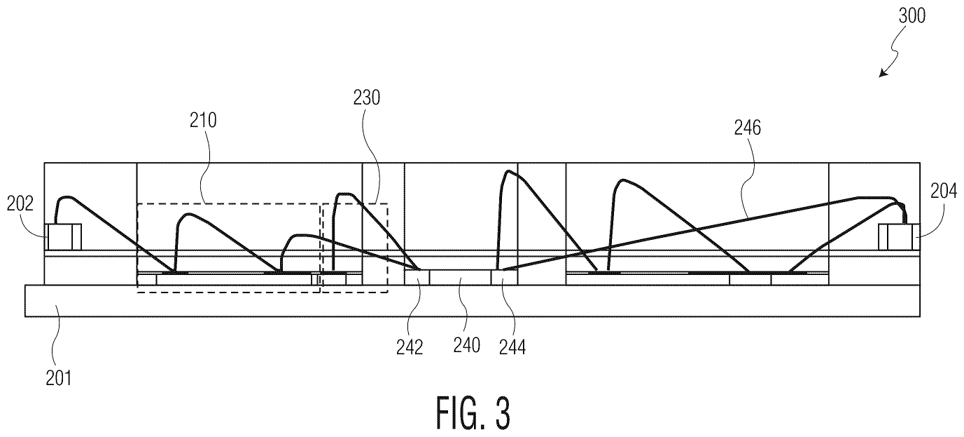

Referring again to FIG. 1, various embodiments of RF amplifier devices may include at least one input-side integrated passive devices (IPDs) (e.g., IPD 220, FIGS. 2 and 3) configured to implement portions of the fundamental match circuit 110 and the harmonic termination circuit 130. More specifically, each IPD may include a semiconductor substrate with one or more integrated passive components.

In other embodiments, some portions of the fundamental match circuit 110 and/or harmonic termination circuit 130 may be implemented as distinct/discrete components or as portions of other types of assemblies (e.g., a low-temperature co-fired ceramic (LTCC) device, a small PCB assembly, and so on). In still other embodiments, some portions of the fundamental match circuit 110 and/or harmonic termination circuit 130 may be coupled to and/or integrated within the semiconductor die that includes transistor 140. The below, detailed description of embodiments that include IPDs should not be taken to limit the inventive subject matter, and the term “passive device substrate” or “IPD substrate” means any type of structure that includes a passive device, including an IPD, a LTCC device, a transistor die, a PCB assembly, and so on.

Amplifier 100 may be implemented in a discrete, packaged power amplifier device, in some embodiments, or in a PCB-based module, in other embodiments. In such devices, input lead 102 and output lead 104 can be coupled to a support substrate, and components associated with the amplifier 100 also are coupled to the substrate. A power amplifier die housing transistor 140, along with the fundamental match circuit 110 and harmonic termination circuit 130, can be included as some of these components within the packaged device or module.

In the field of high-power RF power amplifier (e.g., for use in cellular base stations and other applications, broadband power amplification using silicon-based devices (e.g., LDMOS power transistor devices with output matching networks) has been successfully achieved. However, such silicon-based devices can, in some circumstances, exhibit relatively low efficiencies and power densities when compared with the efficiencies and power densities of GaN-based power amplifier devices.

Accordingly, GaN-based power amplifier devices have been increasingly considered for high power broadband applications. However, there are challenges to using GaN technology to achieve broadband power amplification (e.g., over 20 percent fractional bandwidth).

For example, nonlinear input capacitance of RF power devices associated with some GaN transistors are known to generate harmonics and intermodulation distortion that can impair efficiency and linearity. For example, signal energy at the second harmonic of the center frequency of operation (f0), of the amplifier 300 (also referred to herein as the “fundamental frequency” of operation) may degrade the performance of the amplifier, if not compensated for.

Accordingly, second harmonic termination circuits can also play an important role in the overall performance of a power amplifier design that uses GaN-based transistors. Without the information of second harmonic impedance at the current source terminal plane, it can be difficult to tune a power amplifier to achieve relatively high fractional bandwidth with good performance. Furthermore, the second harmonic termination may vary significantly across a large bandwidth for broadband applications, which can further increase the difficulty of circuit tuning.

To overcome or potentially mitigate these and other challenges in designing broadband power amplifiers using GaN-based devices, embodiments disclosed herein can include “pseudo” and “true” inverse class F amplifier circuits, partially implemented with a high-power packaged power transistor device with unique, in-package, input and output impedance matching topologies.

Class F and inverse class F amplifiers are characterized by having a 50 percent conduction angle and can operate in a switching mode. A conventional class F amplifier may include one or more odd harmonic resonators in its output network to shape the drain-to-source voltage (V_{DS}) so that the transistor switching loss is reduced and the efficiency is increased. In contrast, a conventional inverse class F amplifier may have one or more even harmonic resonators in its output network to shape the drain-to-source voltage (e.g., to shape the drain current to be a square wave and the drain-to-source voltage to be a sine wave).

To illustrate, FIG. 2 is a top view of an embodiment of a packaged RF amplifier device 200 that embodies amplifier 100 of FIG. 1 FIG. 3 is a side view of packaged RF amplifier device 200. As will be described in more detail below, device 200 includes a power transistor die 240 (e.g., including transistor 140 of FIG. 1) and an input-side IPDs 220. IPD 220 includes components configured to implement fundamental match circuit 210 (e.g., fundamental match circuit 110 of FIG. 1) and harmonic termination circuit 230 (e.g., harmonic termination circuit 130 of FIG. 1).

Device 200 includes a flange 201 (or “device substrate”), in an embodiment, which may include a rigid electrically- and thermally-conductive substrate with a thickness that is sufficient to provide structural support for various electrical components and elements of device 200. Flange 201 has top and bottom surfaces, where the top surface is visible in FIG. 2. According to an embodiment, flange 201 may function as a heat sink for transistor die 240. Further, flange 201 may correspond to a ground reference node for the device 200 (and more particularly for transistor die 240 and IPDs 220 and 250). For example, various components and elements may have terminals that are electrically coupled to flange 201, and flange 201 may be electrically coupled to a system ground when the device 200 is incorporated into a larger electrical system. At least the top surface of flange 201 is formed from a layer of conductive material, and possibly all of flange 201 is formed from bulk conductive material.

Although not shown in FIGS. 2 and 3, an isolation structure may be attached to the top surface of flange 201, in an embodiment. The isolation structure, which is formed from a rigid, electrically insulating material, provides electrical isolation between conductive features of the device (e.g., between leads 202, 204 and flange 201). The isolation structure may have a frame shape, in an embodiment, which includes a substantially enclosed, four-sided structure with a central opening. Alternatively, the isolation structure may have another shape (e.g., annular ring, oval, and so on).

A portion of the top surface of flange 201 that is exposed through the opening in the isolation structure is referred to herein as the “active area” of device 200. Transistor die 240 and IPDs 220 and 250 are positioned within the active device area of device 200, and are physically and electrically coupled to the top surface of the flange 201. For example, the transistor die 240 and IPDs 220 and 250 may be coupled to the top surface of flange 201 using conductive epoxy, solder, solder bumps, sintering, and/or eutectic bonds.

Device 200 may be incorporated in an air cavity package, in which the power transistor die 240 and the IPDs 220 and 250 are located within an enclosed air cavity. In that case, the air cavity is bounded by flange 201, the isolation structure (not shown), and a cap (not shown) overlying and in contact with the isolation structure and leads 202 and 204. In other embodiments, the components of device 200 may be incorporated into an overmolded package (i.e., a package in which the electrical components within the active area of the device are encapsulated with a non-conductive molding compound, and in which portions of the leads 202, 204 also may be encompassed by the molding compound). In still other embodiments, the components of device 200 may be incorporated into a no-leads package (e.g., a dual flat no-leads (DFN) or quad flat no-leads (QFN) package), or into other types of packages.

Regardless of the type of packaging utilized, device 200 houses a single amplification path that represents a physical implementation of amplifier circuit 100 (FIG. 1). The amplification path embodied in device 200 includes an input lead 202 (e.g., input 102, FIG. 1), an output lead 204 (e.g., output 104, FIG. 1), a power transistor die 240 (e.g., embodying transistor 140, FIG. 1), an input-side impedance matching circuit 210 (e.g., fundamental match circuit 110, FIG. 1), and an input-side harmonic termination circuit 230 (e.g., harmonic termination circuit 130, FIG. 1). Device 200 includes an output network implemented at least partially by IPD 250 (e.g., output network 150 of FIG. 1) that may include an output-side impedance matching circuit and/or an output-side harmonic termination circuit.

The input and output leads 202, 204 may be mounted on a top surface of the isolation structure on opposed sides of the central opening. Generally, the input and output leads 202, 204 are oriented to allow for attachment of bond wires between the input and output leads 202, 204 and components and elements within the central opening of isolation structure.

Transistor die 240 includes an integrated power transistor 241 (e.g., transistor 140, FIG. 1). The transistor 241 has a collection of (in this example, six) input terminals 242 (e.g., collectively, input terminal 142, FIG. 1) and two current-carrying terminals including output terminal 244 (e.g., output/drain terminal 144) and a source terminal (e.g., source terminal 145, FIG. 1), not shown that may be connected to flange 201 as a ground reference node.

Output terminal 244 of transistor die 240 is connected to output leads 204 through a set of bond wires.

The output bondpad 244 (and thus the first current-carrying terminal of transistor 241) is electrically coupled to the output lead 204 through a set of bondwires 246. Note that, in FIG. 2, for convenience of illustration, only one bondwire is referenced for each of the various sets of bond wires discussed herein. In this approach, all bondwires that connect between the same two elements are considered to be within the same set of bondwires. Further, although in FIG. 2 each set of bond wires is shown to include a particular number of bond wires, each set of bond wires may include fewer or more bond wires than is illustrated. Generally, for any particular set of bond wires, the number of bond wires and the bond wire profile/length determine a desired inductance value associated with the set of bond wires.

Referring again to transistor die 240, the input bondpad 242 (and thus the input terminal of transistor 241) is coupled through the fundamental match circuit 210 (e.g., circuit 110, FIG. 1) and the harmonic termination circuit 230 (e.g., circuit 130, FIG. 1) to the input lead 202 (e.g., input 102, FIG. 1).

In other words, the fundamental match circuit 210 (e.g., circuit 110, FIG. 1) and harmonic termination circuit 230 (e.g., circuit 130, FIG. 1) are electrically coupled between the input lead 202 (e.g., input 102, FIG. 1) and input terminal 242 of transistor die 240 (and thus to the input terminal of transistor 241).

According to the illustrated embodiment, portions of the fundamental match circuit 210 (e.g., circuit 110, FIG. 1) are embodied in a single IPD 220 that is coupled to the top surface of the flange 201 between the input lead 202 and the transistor die 240. More specifically, the portions of the fundamental match circuit embodied within IPD 220 include a first shunt capacitance 214 (e.g., shunt capacitor 114, FIG. 1) and a second shunt capacitor 218 (e.g., capacitor 118, FIG. 1). Other portions of fundamental match circuit 210, and in particular other inductive portions, are implemented using bondwires 212, 216, 222 (e.g., inductor 112, inductor 116, and inductor 122 of FIG. 1).

As discussed previously in conjunction with FIG. 1, according to an embodiment, the fundamental match circuit includes a DITM circuit with a first inductance in the form of a first set of bondwires 212 (e.g., first inductive element 112, FIG. 1) with first ends coupled to input lead 202 (e.g., input 102, FIG. 1) and second ends coupled to a terminal of first shunt capacitor 214 (e.g., node 115 of FIG. 1). Shunt capacitor 214 (e.g., capacitance 114, FIG. 1) has a second terminal coupled to a ground reference node (e.g., to flange 201). In addition, the DITM circuit further includes a second inductance in the form of a second set of bond wires 216 (e.g., second inductive element 116, FIG. 1) with first ends coupled to the first terminal of first shunt capacitance 214 and second ends coupled to a first terminal of second shunt capacitance 218 (e.g., capacitor 118 of FIG. 1). The second terminal of second shunt capacitor 218 is coupled to a ground reference node (e.g., to flange 201). DITM circuit further includes a third inductance in the form of a third set of bond wires 222 (e.g., inductor 122, FIG. 1) with first ends coupled to the first terminal of second shunt capacitance 218 and second ends coupled to input terminals 242 of transistor die 240.

The DITM circuit of fundamental match circuit 210 of FIGS. 2 and 3 may be implemented using multiple parallel DITM circuits coupled between input lead 202 and input terminals 242.

According to the illustrated embodiment, portions of the harmonic termination circuit 230 (e.g., circuit 130, FIG. 1) are also embodied within IPD 220 that is coupled to the top surface of the flange 201 between the input lead 202 and the transistor die 240. More specifically, the portions of the harmonic termination circuit 230 embodied within IPD 220 include an inductor formed by bond wires 231 (e.g., inductor 131, FIG. 1) that are connected between input terminals 242 of 240 (e.g., input terminal 142 of FIG. 1) and a first terminal of capacitor 233 (e.g., capacitance 133 of FIG. 1). A second terminal of capacitor 233 is coupled to a ground reference node (e.g., to flange 201).

In various embodiments of device 200, the electrical connection formed between the first terminal of capacitor 233 and input terminals 242 of transistor die 240 can be formed by any number of bond wires 231. In a specific embodiments, the bond wires 231 connecting to input terminals 242 of transistor die 240 may be configured so that they are evenly spaced along the lengths of input terminals 242. This even spacing of bond wires 231 on input terminals 242 can result in the signal being carried by bond wires 231 uniformly exciting the gate fingers of 241 by ensuring the signals input into input terminals 242 are distributing evenly across the transistor 241. This can improve the power efficiency of the operation of transistor 241 of device 200.

It may be noted that the harmonic termination circuit 230 may be implemented using multiple parallel LC circuits coupled between input terminals 242 and flange 201.

Device 200 includes an output network implemented by IPD 250 (e.g., output network 150, FIG. 1). IPDs 250 includes capacitors 271, 273, and 275. Capacitors 271, 273, and 275 are interconnected by bond wires 277 and 279 to form the desired output network. In various embodiments, the components of IPD 250 may be connected to form an output network that achieves a desired level of impedance matching and harmonic termination.

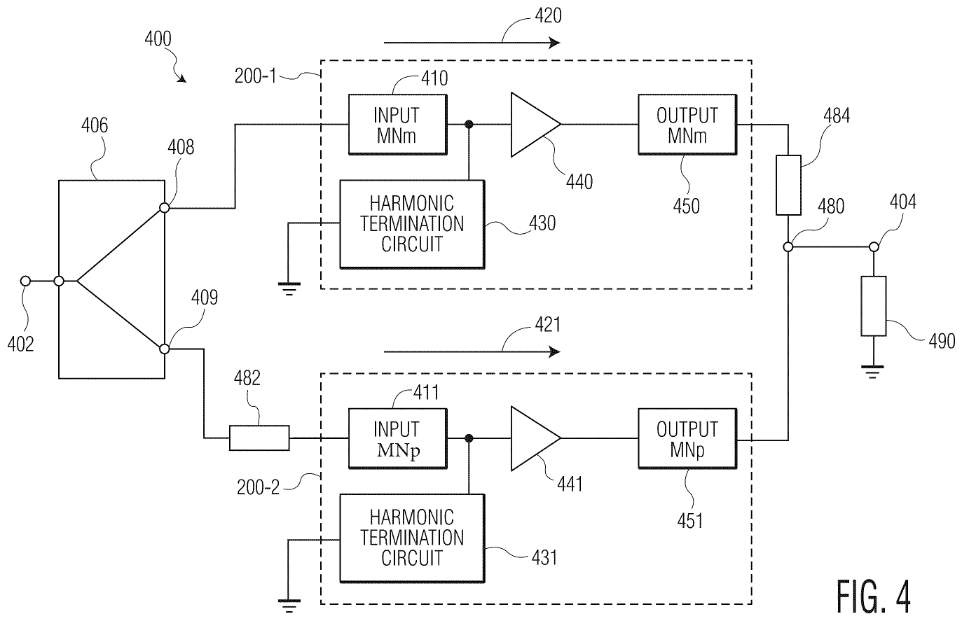

Device 200 embodies a single amplification path between input and output leads 202, 204. When incorporated into a multiple-path amplifier, such as the Doherty amplifier 400 described below in conjunction with FIG. 4, the amplification path embodied in device 200 may correspond to a main amplifier path (e.g., main amplifier path 420, FIG. 4), or the amplification path may correspond to a peaking amplifier path (e.g., peaking amplifier path 421, FIG. 4). Accordingly, two instances of device 200 may be utilized to provide both the main and peaking amplifier paths of the Doherty amplifier, although some of the individual components may have differences (e.g., the power transistor in the peaking amplifier path may be larger than the power transistor in the main amplifier path). In an alternate embodiment, device 200 could be modified to include two amplification paths implemented in parallel within the same package (e.g., the device could include two input leads, two output leads, and two instances of the circuitry depicted in FIGS. 2 and 3), in order to be more efficiently utilized in a multiple-path amplifier.

For example, FIG. 4 is a simplified schematic diagram of a Doherty power amplifier 400 in which two parallel instances of RF power amplifier circuit 200 may be implemented. Amplifier 400 includes an input node 402, an output node 404, a power divider 406 (or splitter), a main amplifier path 420, a peaking amplifier path 421, and a combining node 480. A load 490 may be coupled to the combining node 480 (e.g., through an impedance transformer, not shown) to receive an amplified RF signal from amplifier 400.

Power divider 406 is configured to divide the power of an input RF signal received at input node 402 into main and peaking portions of the input signal. The main input signal is provided to the main amplifier path 420 at power divider output 408, and the peaking input signal is provided to the peaking amplifier path 421 at power divider output 409. During operation in a full-power mode when both the main and peaking amplifiers 440, 441 are supplying current to the load 490, the power divider 406 divides the input signal power between the amplifier paths 420, 421. For example, the power divider 406 may divide the power equally, such that roughly one half of the input signal power is provided to each path 420, 421 (e.g., for a symmetric Doherty amplifier configuration). Alternatively, the power divider 406 may divide the power unequally (e.g., for an asymmetric Doherty amplifier configuration).

Essentially, the power divider 406 divides an input RF signal supplied at the input node 402, and the divided signals are separately amplified along the main and peaking amplifier paths 420, 421. The amplified signals are then combined in phase at the combining node 480. It can be important that phase coherency between the main and peaking amplifier paths 420, 421 is maintained across a frequency band of interest to ensure that the amplified main and peaking signals arrive in phase at the combining node 480, and thus to ensure proper Doherty amplifier operation.

Each of the main amplifier 440 and the peaking amplifier 441 includes one or more single-stage or multiple-stage power transistor dies (e.g., die 240, FIGS. 2 and 3) for amplifying an RF signal conducted through the amplifier 440, 441. According to various embodiments, all amplifier stages or a final amplifier stage of either or both the main amplifier 440 and/or the peaking amplifier 441 may be implemented, for example, using a III-V field effect transistor (e.g., a HEMT), such as a GaN FET (or another type of III-V transistor, including a GaAs FET, a GaP FET, an InP FET, or an InSb FET). Where only one of the main amplifier 440 or the peaking amplifier 441 is implemented as a III-V FET, the other amplifier may be implemented as a silicon-based FET (e.g., an LDMOS FET), in some embodiments.

Although the main and peaking power transistor dies may be of equal size (e.g., in a symmetric Doherty configuration), the main and peaking power transistor dies may have unequal sizes, as well (e.g., in various asymmetric Doherty configurations). In an asymmetric Doherty configuration, the peaking power transistor die typically is larger than the main power transistor die by some multiplier. For example, the peaking power transistor die may be twice the size of the main power transistor die so that the peaking power transistor die has twice the current-carrying capability of the main power transistor die. Peaking-to-main amplifier die size ratios other than a 2:1 ratio may be implemented, as well.

During operation of Doherty amplifier 400, the main amplifier 440 is biased to operate in class AB mode, and the peaking amplifier 441 is biased to operate in class C mode. At low power levels, where the power of the input signal at node 402 is lower than the turn-on threshold level of peaking amplifier 441, the amplifier 400 operates in a low-power (or back-off) mode in which the main amplifier 440 is the only amplifier supplying current to the load 490. When the power of the input signal exceeds a threshold level of the peaking amplifier 441, the amplifier 400 operates in a high-power mode in which the main amplifier 440 and the peaking amplifier 441 both supply current to the load 490. At this point, the peaking amplifier 441 provides active load modulation at combining node 480, allowing the current of the main amplifier 440 to continue to increase linearly.

Input and output impedance matching networks 410, 450 (input MNm, output MNm) may be implemented at the input and/or output of the main amplifier 440. Similarly, input and output impedance matching networks 411, 451 (input MNp, output MNp) may be implemented at the input and/or output of the peaking amplifier 441. In each case, the matching networks 410, 411, 450, 451 may be used to transform the gate and drain impedances of main amplifier 440 and peaking amplifier 441 to a more desirable system level impedance, as well as manipulate the signal phases to ensure proper Doherty amplifier operation. All or portions of the input and output impedance matching networks 410, 411, 450, 451 may be implemented inside a power transistor package that includes the main and/or peaking amplifiers 440, 441, or some portions of the input and output impedance matching networks 410, 411, 450, 451 may be implemented on a PCB or other substrate to which a power transistor package is mounted. According to an embodiment, each of the input impedance matching networks 410, 411 may have the same or similar configuration as the fundamental matching circuits (e.g., circuit 110, FIG. 1) described above.

In addition, embodiments of the inventive subject matter include harmonic frequency termination circuits 430, 431 (e.g., instances of harmonic termination circuit 130, FIG. 1) coupled between the inputs of amplifiers 440, 441 and a ground reference node. The harmonic termination circuits 430, 431 are configured to control the harmonic impedance across a relatively wide fractional bandwidth. For example, the harmonic termination circuits 430, 431 may provide a low impedance path to ground for signal energy at the second harmonic of the fundamental frequency of operation of the amplifier 400.

As indicated in FIG. 4 with dashed-line boxes 200-1, 200-2, the input matching circuit 410, amplifier 440, harmonic termination circuit 430, and output network 450 for the main amplification path 420 may be implemented using a first instance of device 200, and the input matching circuit 411, amplifier 441, harmonic termination circuit 431, and output network 451 for the peaking amplification path 421 may be implemented using a second instance of device 200. In an alternate embodiment, and as discussed previously, the above-listed components for the main and peaking amplification paths may be combined into a single package body.

Doherty amplifier 400 has a “non-inverted” load network configuration. In the non-inverted configuration, the input circuit is configured so that an input signal supplied to the peaking amplifier 441 is delayed by 90 degrees with respect to the input signal supplied to the main amplifier 440 at the fundamental frequency of operation of the amplifier 400. To ensure that the main and peaking input RF signals arrive at the main and peaking amplifiers 440, 441 with about 90 degrees of phase difference, as is fundamental to proper Doherty amplifier operation, phase delay element 482 applies about 90 degrees of phase delay to the peaking input signal. For example, phase delay element 482 may include a quarter wave transmission line, or another suitable type of delay element with an electrical length of about 90 degrees.

To compensate for the resulting 90 degree phase delay difference between the main and peaking amplifier paths 420, 421 at the inputs of amplifiers 440, 441 (i.e., to ensure that the amplified signals arrive in phase at the combining node 480), the output circuit is configured to apply about a 90 degree phase delay to the signal between the output of main amplifier 440 and the combining node 480. This is achieved through an additional delay element 484. Alternate embodiments of Doherty amplifiers may have an “inverted” load network configuration. In such a configuration, the input circuit is configured so that an input signal supplied to the main amplifier 440 is delayed by about 90 degrees with respect to the input signal supplied to the peaking amplifier 441 at the center frequency of operation of the amplifier 400, and the output circuit is configured to apply about a 90 degree phase delay to the signal between the output of peaking amplifier 441 and the combining node 480.

In some RF amplifier implementations, for relatively low operational frequencies (e.g., at 1 GHz or less) the required inductances and capacitances of the amplifier's input matching circuitry require values that can be difficult to implement with a single IPD configuration (e.g., the configuration depicted in FIG. 2).

Accordingly, an alternate implementation of the second harmonic terminating component of an amplifiers input circuit is presented that is optimized for lower frequency operations.

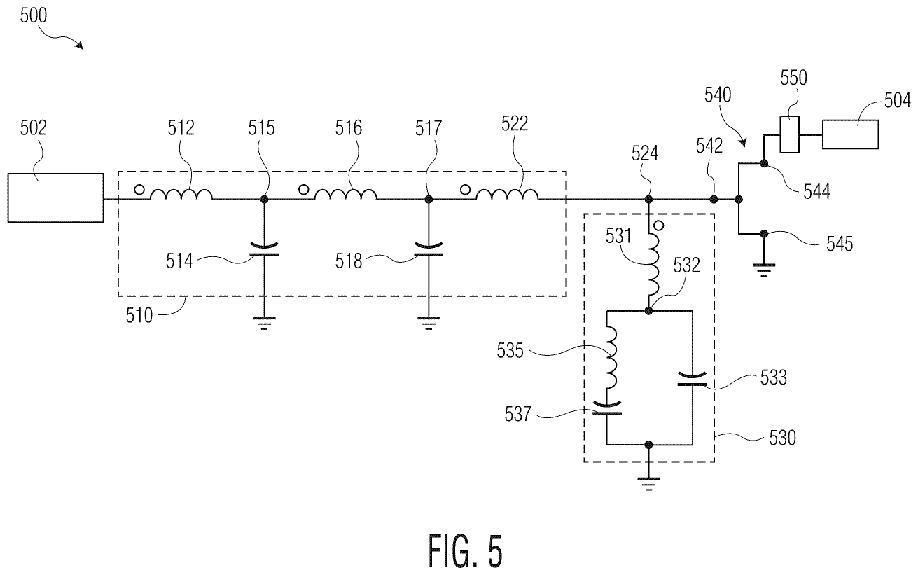

Specifically, FIG. 5 is a schematic diagram of an RF power amplifier circuit 500. Power amplifier circuit 500 includes an input lead 502, an input fundamental frequency impedance matching circuit 510 (“fundamental match circuit”), a second harmonic frequency termination circuit 530 (“harmonic termination circuit”), a transistor 540, and an output lead 504, in an embodiment. Each of the input and output leads 502, 504 may be more generally referred to as an “RF input/output (I/O).” Further, reference is made below to a “ground reference node.” In various embodiments, a “ground reference node” is a conductive feature of a device or module (e.g. a conductive flange, a die pad, or a conductive ground plane in a printed circuit board (PCB) based module) to which terminals of various components of the power amplifier circuit 500 are coupled, where that conductive feature may be coupled to system ground (e.g., to a zero volt ground reference or to another voltage reference) when the device or module is incorporated into a larger electrical system.

Input lead 502 and output lead 504 each may include a conductor (e.g., a package lead), which is configured to enable the power amplifier circuit 500 to be electrically coupled with external circuitry (not shown). More specifically, the input and output leads 502, 504 are physically positioned to span between the exterior and the interior of a device package or module, in an embodiment. Fundamental match circuit 510 and harmonic termination circuit 530 are electrically coupled between the input 502 and an input terminal 542 of transistor 540 (also referred to as a “transistor input terminal”, a “control terminal” or a “gate terminal”). A first current-carrying terminal 544 of transistor 540 (e.g., the drain terminal) is coupled to the output 504 through an output network 550, that may include various impedance matching and filtering components. A second current-carrying terminal 545 of transistor 540 (e.g., the source terminal) is coupled to a ground reference node.

According to an embodiment, transistor 540 is the primary active component of circuit 500. Transistor 540 includes a control terminal 542 and two current-carrying terminals 544, 545, where the current-carrying terminals 544, 545 are spatially and electrically separated by a variable-conductivity channel. For example, transistor 540 may be a field effect transistor (FET), which includes a gate terminal (i.e., control terminal 542), a drain terminal (i.e., first current-carrying terminal 544), and a source terminal (i.e., second current-carrying terminal 545). According to an embodiment, and using nomenclature typically applied to FETs in a non-limiting manner, the gate terminal 542 of transistor 540 is coupled to the fundamental match circuit 510 and the harmonic termination circuit 530, the drain terminal 544 of transistor 540 is coupled to the output 504, and the source terminal 545 of transistor 540 is coupled to ground (or another voltage reference). Through the variation of control signals provided to the gate terminal of transistor 540, the current between the current-carrying terminals of transistor 540 may be modulated.

According to various embodiments, transistor 540 is a Ill-V field effect transistor (e.g., a high electron mobility transistor (HEMT)), which has a nonlinear input capacitance and a relatively low drain terminal-source terminal capacitance, Cds, when compared with a silicon-based FET (e.g., a laterally-diffused metal oxide semiconductor (LDMOS) FET). According to an embodiment, transistor 540 may have a drain terminal-source terminal capacitance that is less than about 0.2 pF/W. Further, in some embodiments, transistor 540 may be a GaN FET, although in other embodiments, transistor 540 may be another type of Ill-V transistor (e.g., gallium arsenide (GaAs), gallium phosphide (GaP), indium phosphide (InP), or indium antimonide (InSb)), or another type of transistor that has a nonlinear input capacitance and a relatively low drain terminal-source terminal capacitance.

Fundamental match circuit 510 and harmonic termination circuit 530 are electrically coupled between the input 502 and a first terminal 542 of transistor 540 (e.g., the gate terminal). More specifically, the fundamental match circuit 510 is coupled between input 502 and a second node 524, which, in turn, is coupled to the control terminal 542 (e.g., gate terminal) of the transistor 540. Fundamental match circuit 510 is configured to transform (e.g., raise) the gate impedance of transistor 540 to a higher (e.g., intermediate or higher) impedance level (e.g., in a range from about 2 to about 10 ohms or higher) at node 502.

According to an embodiment, fundamental match circuit 510 is configured as a DITM circuit. More specifically, and according to the illustrated embodiment, the fundamental match circuit 510 includes a DITM match circuit composed of inductor 512 (e.g., a set of bond wires) coupled between input 502 and node 515 (also referred to as a “connection node”). Shunt capacitor 514 is coupled between node 515 and a ground reference node. Inductor 516 (e.g., a set of bond wires) is coupled between node 515 and node 517. Shunt capacitor 518 is connected between node 517 and a ground reference node. Finally, fundamental match circuit 510 includes inductor 522 connected between node 517 and node 524.

According to an embodiment, inductors 512, 516, and 522, in combination with shunt capacitors 514 and 518 form the DITM match circuit of fundamental match circuit 510. In some embodiments, inductor 512 may have an inductance that ranges from 30 pico Henries (pH) to 500 pH, shunt capacitor 514 and capacitor 518 may each have capacitances ranging from 10 pico Farads (pF) to 100 pF, and inductor 522 may have an inductance ranging from 30 pH to 700 pH. In other applications, however, these components may be configured differently. Within amplifier 500, harmonic termination circuit 530 is coupled between the second node 524 (or the input terminal 542 (e.g., gate terminal) of transistor 540) and a ground reference node. Accordingly, the second node 524 basically corresponds to an input to harmonic termination circuit 530. Harmonic termination circuit 530 includes an inductor 531 (e.g., a set of bond wires) coupled between the second node 524 (or the input terminal 542 of the transistor 540) and node 532. Capacitor 533 is connected between node 532 and a ground reference node. In parallel with capacitor 533, inductor 535 and capacitor 537 are connected in series between node 532 and the ground reference node.

According to an embodiment, the inductance and capacitance values selected for inductor 535 and capacitances 533, 537 are configured to enable harmonic termination circuit 530 to function as a high impedance path to ground (e.g., effectively an open circuit) for signal energy at the fundamental frequency of operation, and a low impedance path to ground for signal energy at or near a second harmonic frequency (e.g., at the second harmonic frequency or within 50 percent of the second harmonic frequency of amplifier 500).

More specifically, within amplifier 500 the inductances of inductors 512, 516, and 522 are selected to obtain good fundamental performance targeting particular amplifier 500 gain and input impedance characteristics. Harmonic termination circuit 530 is implemented as a second harmonic frequency control network uses the series-connected inductor and tank circuit (comprising inductor 535 and capacitors 533, 537) that is connected between gate or input terminal 542 of transistor 540 and a ground reference node and is used to locate the second harmonic frequency in an optimum location.

Although transistor 540 and various elements of the fundamental match circuit 510 and the harmonic termination circuit 530 are shown as singular components, the depiction is for the purpose of ease of explanation only. Those of skill in the art would understand, based on the description herein, that transistor 540 and/or certain elements of the fundamental match circuit 510 and the harmonic termination circuit 530 each may be implemented as multiple components (e.g., connected in parallel or in series with each other). Further, embodiments may include single-path devices (e.g., including a single input lead, output lead, transistor, etc.), dual-path devices (e.g., including two input leads, output leads, transistors, etc.), and/or multi-path devices (e.g., including two or more input leads, output leads, transistors, etc.). Further, the number of input/output leads may not be the same as the number of transistors (e.g., there may be multiple transistors operating in parallel for a given set of input/output leads). The specific description of transistor 540 and various elements of the fundamental match circuit 510 and the harmonic termination circuit 530 thus are not intended to limit the scope of the inventive subject matter only to the illustrated embodiments.

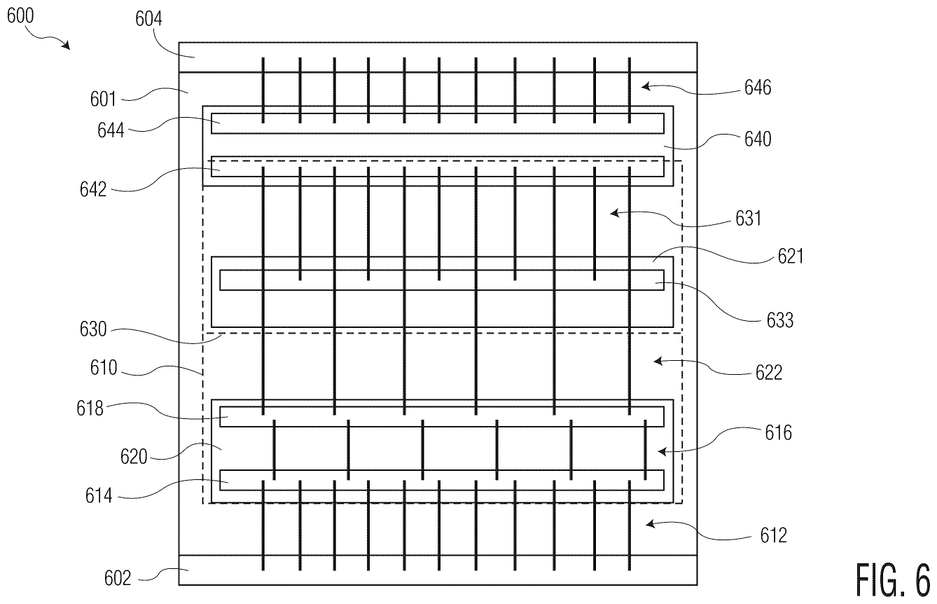

Referring again to FIG. 5, various embodiments of RF amplifier devices may include at least one input-side integrated passive devices (IPDs) (e.g., IPD 620, FIG. 6) configured to implement portions of the fundamental match circuit 510 and the harmonic termination circuit 530. More specifically, each IPD may include a semiconductor substrate with one or more integrated passive components.

In other embodiments, some portions of the fundamental match circuit 510 and/or harmonic termination circuit 530 may be implemented as distinct/discrete components or as portions of other types of assemblies (e.g., a low-temperature co-fired ceramic (LTCC) device, a small PCB assembly, and so on). In still other embodiments, some portions of the fundamental match circuit 510 and/or harmonic termination circuit 530 may be coupled to and/or integrated within the semiconductor die that includes transistor 540. The below, detailed description of embodiments that include IPDs should not be taken to limit the inventive subject matter, and the term “passive device substrate” or “IPD substrate” means any type of structure that includes a passive device, including an IPD, a LTCC device, a transistor die, a PCB assembly, and so on.

Amplifier 500 may be implemented in a discrete, packaged power amplifier device, in some embodiments, or in a PCB-based module, in other embodiments. In such devices, input and output leads 502, 504 can be coupled to a support substrate, and components associated with the amplifier 500 also are coupled to the substrate. A power amplifier die housing transistor 540, along with the fundamental match circuit 510 and harmonic termination circuit 530, can be included as some of these components within the packaged device or module.

FIG. 6 is a top view of an embodiment of a packaged RF amplifier device 600 that embodies portions of amplifier 500 of FIG. 5, as detailed below. As will be described in more detail below, device 600 includes a power transistor die 640 (e.g., including transistor 540 of FIG. 5) and input-side IPD 620 and IPD 621. Together, IPD 620 and IPD 621 include components configured to implement a fundamental match circuit (e.g., fundamental match circuit 510 of FIG. 5) and a harmonic termination circuit (e.g., harmonic termination circuit 530 of FIG. 5).

Device 600 includes a flange 601 (or “device substrate”), in an embodiment, which may include a rigid electrically- and thermally-conductive substrate with a thickness that is sufficient to provide structural support for various electrical components and elements of device 600. Flange 601 has top and bottom surfaces, where the top surface is visible in FIG. 6. According to an embodiment, flange 601 may function as a heat sink for transistor die 640. Further, flange 601 may correspond to a ground reference node for the device 600 (and more particularly for transistor die 640 and IPDs 620 and 621). For example, various components and elements may have terminals that are electrically coupled to flange 601, and flange 601 may be electrically coupled to a system ground when the device 600 is incorporated into a larger electrical system. At least the top surface of flange 601 is formed from a layer of conductive material, and possibly all of flange 601 is formed from bulk conductive material.

Although not shown in FIG. 6, an isolation structure may be attached to the top surface of flange 601, in an embodiment. The isolation structure, which is formed from a rigid, electrically insulating material, can provide electrical isolation between conductive features of the device (e.g., between leads 602, 604 and flange 601). The isolation structure may have a frame shape, in an embodiment, which includes a substantially enclosed, four-sided structure with a central opening. Alternatively, the isolation structure may have another shape (e.g., annular ring, oval, and so on).

A portion of the top surface of flange 601 that is exposed through the opening in the isolation structure can be referred to herein as the “active area” of device 600. Transistor die 640 and IPDs 620 and 621 are positioned within the active device area of device 600, and are physically and electrically coupled to the top surface of the flange 601. For example, the transistor die 640 and IPDs 620 and 621 may be coupled to the top surface of flange 601 using conductive epoxy, solder, solder bumps, sintering, and/or eutectic bonds.

Device 600 may be incorporated in an air cavity package, in which the power transistor die 640 and the IPDs 620 and 621 are located within an enclosed air cavity. In that case, the air cavity is bounded by flange 601, the isolation structure (not shown), and a cap (not shown) overlying and in contact with the isolation structure and leads 602 and 604. In other embodiments, the components of device 600 may be incorporated into an overmolded package (i.e., a package in which the electrical components within the active area of the device are encapsulated with a non-conductive molding compound, and in which portions of the leads 602, 604 also may be encompassed by the molding compound). In still other embodiments, the components of device 600 may be incorporated into a no-leads package (e.g., a dual flat no-leads (DFN) or quad flat no-leads (QFN) package), or into other types of packages.

Regardless of the type of packaging utilized, device 600 houses a single amplification path that represents a portion of the physical implementation of amplifier circuit 500 (FIG. 5) (specifically the input matching network and the power amplifier, but not the output network). The amplification path embodied in device 600 includes an input lead 602 (e.g., input 502, FIG. 5), an output lead 604 (e.g., representing the output terminal or first current-carrying terminal 544, FIG. 5), a power transistor die 640 (e.g., embodying transistor 540, FIG. 5), an input-side impedance matching circuit 610 (e.g., fundamental match circuit 510, FIG. 5), and an input-side harmonic termination circuit 630 (e.g., harmonic termination circuit 530, FIG. 5). In various embodiments, an output network (e.g., output network 550 of FIG. 5) may be coupled to output lead 604.

The input and output leads 602, 604 may be mounted on a top surface of the isolation structure on opposed sides of the central opening. Generally, the input and output leads 602, 604 are oriented to allow for attachment of bond wires between the input and output leads 602, 604 and components and elements within the central opening of isolation structure.

Transistor die 640 includes an integrated power transistor and an input terminal 642 (e.g., input terminal 542, FIG. 1) and two current-carrying terminals including output terminal 644 (e.g., output/drain terminal 544) and a source terminal, not shown, that may be connected to flange 601 as a ground reference node.

Output terminal 644 of transistor die 640 is connected to output lead 604 through a set of bond wires 646. Note that, in FIG. 6, for convenience of illustration, only one bondwire is referenced for each of the various sets of bond wires discussed herein. In this approach, all bondwires that connect between the same two elements are considered to be within the same set of bondwires. Further, although in FIG. 6 each set of bond wires is shown to include a particular number of bond wires, each set of bond wires may include fewer or more bond wires than is illustrated. Generally, for any particular set of bond wires, the number of bond wires and the bond wire profile/length determine a desired inductance value associated with the set of bond wires.

Referring again to transistor die 640, the input bondpad 642 (and thus the input terminal of transistor die 640) is coupled through the fundamental match circuit 610 (e.g., circuit 510, FIG. 5) and the harmonic termination circuit 530 (e.g., circuit 530, FIG. 5) to the input lead 602 (e.g., input 502, FIG. 5).

In other words, the fundamental match circuit 610 and harmonic termination circuit 230 are electrically coupled between the input lead 602 and input terminal 642 of transistor die 640.

According to the illustrated embodiment, portions of the fundamental match circuit 610 are embodied in IPD 620 that is coupled to the top surface of the flange 601 between the input lead 602 and the transistor die 640. More specifically, the portions of the fundamental match circuit embodied within IPD 620 include a first shunt capacitance 614 (e.g., shunt capacitor 514, FIG. 5) and a second shunt capacitor 618 (e.g., capacitor 518, FIG. 1). Other portions of fundamental match circuit 610, and in particular other inductive portions, are implemented using bondwires 612, 616, 622 (e.g., inductor 512, inductor 516, and inductor 522 of FIG. 5).

According to an embodiment, the fundamental match circuit 610 is configured as a DITM circuit with a first inductance in the form of a first set of bondwires 612 with first ends coupled to input lead 602 and second ends coupled to a terminal of first shunt capacitor 614. Shunt capacitor 614 has a second terminal coupled to a ground reference node (e.g., to flange 601). In addition, the DITM circuit further includes a second inductance in the form of a second set of bond wires 616 with first ends coupled to the first terminal of first shunt capacitance 614 and second ends coupled to a first terminal of second shunt capacitance 618. The second terminal of second shunt capacitor 618 is coupled to a ground reference node (e.g., to flange 201). DITM circuit further includes a third inductance in the form of a third set of bond wires 622 with first ends coupled to the first terminal of second shunt capacitance 618 and second ends coupled to input terminal 642 of transistor die 640.

The DITM circuit of fundamental match circuit 610 of FIG. 6 may be implemented using multiple parallel DITM circuits coupled between input lead 602 and input terminals 642.

According to the illustrated embodiment, portions of the harmonic termination circuit 630 (e.g., circuit 530, FIG. 5) are embodied within IPD 621 that is coupled to the top surface of the flange 601 between the input lead 602 and the transistor die 640. More specifically, the portions of the harmonic termination circuit 630 embodied within IPD 621 include an inductor formed by bond wires 631 (e.g., inductor 531, FIG. 5) that are connected between input terminal 642 of transistor die 640 and a first terminal of capacitor 633 (e.g., capacitance 533 of FIG. 5). A second terminal of capacitor 633 is coupled to a ground reference node (e.g., to flange 201). Another capacitor and inductor structure (e.g., mimicking the functionality of inductor 535 and capacitor 537 of FIG. 5) are implemented within IPD 621, although not illustrated in FIG. 6. It may be noted that the harmonic termination circuit 630 may be implemented using multiple parallel LC circuits coupled between input terminal 642 of transistor die 640 and flange 201.

Although not illustrated, device 200 may include an output network implemented by various combinations of IPDs and inductive bondwires (e.g., output network 550, FIG. 5

Device 600 embodies a single amplification path between input and output leads 602, 604. When incorporated into a multiple-path amplifier, such as the Doherty amplifier 400 described above in conjunction with FIG. 4, the amplification path embodied in device 600 may correspond to a main amplifier path (e.g., main amplifier path 420, FIG. 4), or the amplification path may correspond to a peaking amplifier path (e.g., peaking amplifier path 421, FIG. 4). Accordingly, two instances of device 600 may be utilized to provide both the main and peaking amplifier paths of the Doherty amplifier, although some of the individual components may have differences (e.g., the power transistor in the peaking amplifier path may be larger than the power transistor in the main amplifier path). In an alternate embodiment, device 600 could be modified to include two amplification paths implemented in parallel within the same package (e.g., the device could include two input leads, two output leads, and two instances of the circuitry depicted in FIG. 6), in order to be more efficiently utilized in a multiple-path amplifier.

In some aspects, the techniques described herein relate to a radio frequency amplifier, including: an amplifier input; a transistor die including a transistor and a transistor input terminal; a fundamental frequency impedance matching circuit coupled between the amplifier input and the transistor input terminal, wherein the fundamental frequency impedance matching circuit is configured as a dual input T-match (DITM) circuit including a first shunt capacitor and a second shunt capacitor, wherein a first terminal of the first shunt capacitor is connected to the amplifier input by a first bond wire, the first terminal of the first shunt capacitor is connected to a first terminal of the second shunt capacitor by a second bond wire, and the first terminal of the second shunt capacitor is connected to the transistor input terminal by a third bond wire; and a harmonic frequency termination circuit coupled between the transistor input terminal and a first ground reference node.

In some aspects, the techniques described herein relate to a radio frequency amplifier, wherein the harmonic frequency termination circuit includes a fourth bond wire connected between the transistor input terminal and a first terminal of a third capacitor, and a second terminal of the third capacitor is connected to a second ground reference node.

In some aspects, the techniques described herein relate to a radio frequency amplifier, wherein the harmonic frequency termination circuit includes a fourth bond wire connected between the transistor input terminal and a first node, a first inductor connected between the first node and a second ground reference node and a first capacitor connected between the first node and a third ground reference node.

In some aspects, the techniques described herein relate to a radio frequency amplifier, wherein a second terminal of the first shunt capacitor is connected to a second ground reference node and a second terminal of the second shunt capacitor is connected to a third ground reference node.

In some aspects, the techniques described herein relate to a radio frequency amplifier, wherein the fundamental frequency impedance matching circuit and the harmonic frequency termination circuit are incorporated into a first integrated passive device.

In some aspects, the techniques described herein relate to a radio frequency amplifier, further including a device substrate and wherein the transistor die and the first integrated passive device are mounted to the device substrate.

In some aspects, the techniques described herein relate to a radio frequency amplifier, wherein the device substrate includes a conductive flange and the conductive flange is the first ground reference node.

In some aspects, the techniques described herein relate to a radio frequency amplifier, wherein the harmonic frequency termination circuit is configured to shunt signal energy at or near a second harmonic frequency of a fundamental frequency of operation of the radio frequency amplifier to a ground node, while appearing as an open circuit to signal energy at the fundamental frequency.

In some aspects, the techniques described herein relate to a radio frequency amplifier, wherein the transistor has a nonlinear input capacitance.

In some aspects, the techniques described herein relate to a radio frequency amplifier, wherein the transistor is a gallium nitride transistor.

In some aspects, the techniques described herein relate to a packaged radio frequency amplifier, including: a substrate; an input lead on a surface of the substrate; an output lead on the surface of the substrate; a transistor die on the substrate, wherein the transistor die includes a transistor and a transistor input terminal; a fundamental frequency impedance matching circuit coupled between the amplifier input and the transistor input terminal, wherein the fundamental frequency impedance matching circuit is configured as a dual input T-match (DITM) circuit; and a harmonic frequency termination circuit coupled between the transistor input terminal and a first ground reference node.

In some aspects, the techniques described herein relate to a packaged radio frequency amplifier, wherein the fundamental frequency impedance matching circuit includes a first shunt capacitor and a second shunt capacitor, wherein a first terminal of the first shunt capacitor is connected to the input lead by a first bond wire, the first terminal of the first shunt capacitor is connected to a first terminal of the second shunt capacitor by a second bond wire, and the first terminal of the second shunt capacitor is connected to the transistor input terminal by a third bond wire.

In some aspects, the techniques described herein relate to a packaged radio frequency amplifier, wherein the harmonic frequency termination circuit includes a fourth bond wire connected between the transistor input terminal and a first terminal of a third capacitor, and a second terminal of the third capacitor is connected to a second ground reference node.

In some aspects, the techniques described herein relate to a packaged radio frequency amplifier, wherein the harmonic frequency termination circuit includes a fourth bond wire connected between the transistor input terminal and a first node, a first inductor connected between the first node and a second ground reference node and a first capacitor connected between the first node and a third ground reference node.

In some aspects, the techniques described herein relate to a packaged radio frequency amplifier, further including an isolation structure formed over the substrate, wherein the isolation structure defines an active region of the substrate.

In some aspects, the techniques described herein relate to a packaged radio frequency amplifier, further including an integrated passive device attached to the active region of the substrate.

In some aspects, the techniques described herein relate to a packaged radio frequency amplifier, wherein the integrated passive device forms at least a portion of the fundamental frequency impedance matching circuit or the harmonic frequency termination circuit.

In some aspects, the techniques described herein relate to a Doherty amplifier, including: a main amplifier path; and a peaking amplifier path, and wherein at least one of the main amplifier path and the peaking amplifier includes a radio frequency amplifier, the radio frequency amplifier including: a substrate; an input lead on a surface of the substrate; an output lead on the surface of the substrate; a transistor die on the substrate, wherein the transistor die includes a transistor and a transistor input terminal; a fundamental frequency impedance matching circuit coupled between the amplifier input and the transistor input terminal, wherein the fundamental frequency impedance matching circuit is configured as a dual input T-match (DITM) circuit; and a harmonic frequency termination circuit coupled between the transistor input terminal and a first ground reference node.

In some aspects, the techniques described herein relate to a Doherty amplifier, further including: an isolation structure formed over the substrate, wherein the isolation structure defines an active region of the substrate; and an integrated passive device attached to the active region of the substrate.

In some aspects, the techniques described herein relate to a Doherty amplifier, wherein the integrated passive device forms at least a portion of the fundamental frequency impedance matching circuit or the harmonic frequency termination circuit.

The preceding detailed description is merely illustrative in nature and is not intended to limit the embodiments of the subject matter or the application and uses of such embodiments.

As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed:

1. A radio frequency amplifier, comprising:
an amplifier input;
a transistor die including a transistor and a transistor input terminal;
a fundamental frequency impedance matching circuit coupled between the amplifier input and the transistor input terminal, wherein the fundamental frequency impedance matching circuit is configured as a dual input T-match (DITM) circuit including a first shunt capacitor and a second shunt capacitor, wherein a first terminal of the first shunt capacitor is connected to the amplifier input by a first bond wire, the first terminal of the first shunt capacitor is connected to a first terminal of the second shunt capacitor by a second bond wire, and the first terminal of the second shunt capacitor is connected to the transistor input terminal by a third bond wire; and
a harmonic frequency termination circuit coupled between the transistor input terminal and a first ground reference node.

2. The radio frequency amplifier of claim 1, wherein the harmonic frequency termination circuit includes a fourth bond wire connected between the transistor input terminal and a first terminal of a third capacitor, and a second terminal of the third capacitor is connected to a second ground reference node.

3. The radio frequency amplifier of claim 1, wherein the harmonic frequency termination circuit includes a fourth bond wire connected between the transistor input terminal and a first node, a first inductor connected between the first node and a second ground reference node and a first capacitor connected between the first node and a third ground reference node.

4. The radio frequency amplifier of claim 1, wherein a second terminal of the first shunt capacitor is connected to a second ground reference node and a second terminal of the second shunt capacitor is connected to a third ground reference node.

5. The radio frequency amplifier of claim 1, wherein the fundamental frequency impedance matching circuit and the harmonic frequency termination circuit are incorporated into a first integrated passive device.

6. The radio frequency amplifier of claim 5, further comprising a device substrate and wherein the transistor die and the first integrated passive device are mounted to the device substrate.

7. The radio frequency amplifier of claim 6, wherein the device substrate includes a conductive flange and the conductive flange is the first ground reference node.

8. The radio frequency amplifier of claim 1, wherein the harmonic frequency termination circuit is configured to shunt signal energy at or near a second harmonic frequency of a fundamental frequency of operation of the radio frequency amplifier to a ground node, while appearing as an open circuit to signal energy at the fundamental frequency.

9. The radio frequency amplifier of claim 1, wherein the transistor has a nonlinear input capacitance.

10. The radio frequency amplifier of claim 9, wherein the transistor is a gallium nitride transistor.

11. A packaged radio frequency amplifier, comprising:
a substrate;
an input lead on a surface of the substrate;
an output lead on the surface of the substrate;
a transistor die on the substrate, wherein the transistor die includes a transistor and a transistor input terminal;
a fundamental frequency impedance matching circuit coupled between the amplifier input and the transistor input terminal, wherein the fundamental frequency impedance matching circuit is configured as a dual input T-match (DITM) circuit; and
a harmonic frequency termination circuit coupled between the transistor input terminal and a first ground reference node.

12. The packaged radio frequency amplifier of claim 11, wherein the fundamental frequency impedance matching circuit includes a first shunt capacitor and a second shunt capacitor, wherein a first terminal of the first shunt capacitor is connected to the input lead by a first bond wire, the first terminal of the first shunt capacitor is connected to a first terminal of the second shunt capacitor by a second bond wire, and the first terminal of the second shunt capacitor is connected to the transistor input terminal by a third bond wire.

13. The packaged radio frequency amplifier of claim 11, wherein the harmonic frequency termination circuit includes a fourth bond wire connected between the transistor input terminal and a first terminal of a third capacitor, and a second terminal of the third capacitor is connected to a second ground reference node.

14. The packaged radio frequency amplifier of claim 11, wherein the harmonic frequency termination circuit includes a fourth bond wire connected between the transistor input terminal and a first node, a first inductor connected between the first node and a second ground reference node and a first capacitor connected between the first node and a third ground reference node.

15. The packaged radio frequency amplifier of claim 11, further comprising an isolation structure formed over the substrate, wherein the isolation structure defines an active region of the substrate.

16. The packaged radio frequency amplifier of claim 15, further comprising an integrated passive device attached to the active region of the substrate.

17. The packaged radio frequency amplifier of claim 16, wherein the integrated passive device forms at least a portion of the fundamental frequency impedance matching circuit or the harmonic frequency termination circuit.

18. A Doherty amplifier, comprising:
a main amplifier path; and
a peaking amplifier path, and wherein at least one of the main amplifier path and the peaking amplifier includes a radio frequency amplifier, the radio frequency amplifier including:
a substrate;
an input lead on a surface of the substrate;
an output lead on the surface of the substrate;
a transistor die on the substrate, wherein the transistor die includes a transistor and a transistor input terminal;
a fundamental frequency impedance matching circuit coupled between the amplifier input and the transistor input terminal, wherein the fundamental frequency impedance matching circuit is configured as a dual input T-match (DITM) circuit; and
a harmonic frequency termination circuit coupled between the transistor input terminal and a first ground reference node.

19. The Doherty amplifier of claim 18, further comprising:
an isolation structure formed over the substrate, wherein the isolation structure defines an active region of the substrate; and
an integrated passive device attached to the active region of the substrate.

20. The Doherty amplifier of claim 19, wherein the integrated passive device forms at least a portion of the fundamental frequency impedance matching circuit or the harmonic frequency termination circuit.
